(19) United States
(12) Patent Application Publication
(10) Pub. No.: US 2021/0325601 A1
(43) Pub. Date: Oct. 21, 2021

(54) HOMOGENEOUS INTEGRATED INFRARED PHOTONIC CHIP AND METHOD FOR MANUFACTURING SAME

(71) Applicant: NANJING UNIVERSITY OF POSTS AND TELECOMMUNICATIONS, Nanjing (CN)

(72) Inventors: Yongjin WANG, Nanjing (CN); Shuyu NI, Nanjing (CN); Xin LI, Nanjing (CN)

(73) Assignee: NANJING UNIVERSITY OF POSTS AND TELECOMMUNICATIONS, Nanjing (CN)

(21) Appl. No.: 17/360,942

(22) Filed: Jun. 28, 2021

Related U.S. Application Data
(63) Continuation of application No. PCT/CN2019/112932, filed on Oct. 24, 2019.

(30) Foreign Application Priority Data
Dec. 28, 2018 (CN) 201811624876.8

(51) Int. Cl. G02B 6/10; H01L 33/00; H01L 33/06; H01L 33/24; H01L 33/12; H01L 33/30; H01L 31/0352; H01L 31/0392; H01L 31/0304; H01L 31/18; G02B 6/136; G02B 6/132

(52) U.S. Cl. CPC G02B 6/102; H01L 33/0062; H01L 33/06; H01L 33/24; H01L 33/12; H01L 33/30; G02B 6/132; H01L 31/035281; H01L 31/0392; H01L 31/03046; H01L 31/1844; G02B 6/136; H01L 31/035236

(57) ABSTRACT

A homogeneous integrated infrared photonic chip and a method for manufacturing the same are provided. The homogeneous integrated infrared photonic chip includes a substrate layer, and a device structure and a waveguide structure that are both positioned on a surface of the substrate layer; wherein the device structure includes a lower contact layer, a quantum well layer, and an upper contact layer that are sequentially stacked along a direction perpendicular to the substrate layer, and the substrate layer, the lower contact layer, the quantum well layer, and the upper contact layer are made of a III-V material; and wherein the waveguide structure includes a waveguide layer made of the III-V material, the waveguide layer and the lower contact layer being arranged in the same layer.

### CROSS-REFERENCE TO RELATED APPLICATIONS

This application is a continuation of PCT Patent Application No. PCT/CN2019/112932 filed on Oct. 24, 2019, which claims the priority of Chinese Patent Application No. CN201811624876.8 filed on Dec. 28, 2018, the entire content of both of which is hereby incorporated by reference for all purposes.

### TECHNICAL FIELD

The present disclosure relates to the technical fields of information materials and devices, and in particular, relates to a homogeneous integrated infrared photonic chip and a method for manufacturing the same.

### BACKGROUND

Infrared light emitting diodes (LED) are capable of emitting infrared rays, and are applicable to the fields of security supervision, wearable devices, infrared communications, infrared remote controls, sensor light sources and night illuminations, and the like, particularly applicable to the field of gas detection. However, only independent infrared LEDs or infrared receiver diodes are present at the market. Therefore, during manufacturing of infrared communication devices, diode devices and waveguide devices need to be separately manufactured on different materials. That is, the infrared communication devices in the related art are all heterogeneous integrated devices. This greatly increases manufacturing difficulty and manufacturing cost of the infrared communication devices.

Therefore, how to reduce the manufacturing difficulty and the manufacturing cost of the infrared light communication device is an urgent technical problem to be solved.

### SUMMARY

The present disclosure provides a homogeneous integrated infrared photonic chip and a method for manufacturing the same.

A homogeneous integrated infrared photonic chip is provided in a first aspect of the present disclosure. The homogeneous integrated infrared photonic chip includes a substrate layer, a device structure, and a waveguide structure, wherein the device structure and the waveguide structure are both disposed on a surface of the substrate layer; wherein the device structure comprises a lower contact layer, a quantum well layer, and an upper contact layer; the lower contact layer, the quantum well layer, and the upper contact layer are sequentially stacked along a direction perpendicular to the substrate layer; and the substrate layer, the lower contact layer, the quantum well layer, and the upper contact layer are made of a III-V material; and wherein the waveguide structure comprises a waveguide layer made of the III-V material, and the waveguide layer and the lower contact layer are disposed in one same layer.

A method for manufacturing a homogeneous integrated infrared photonic chip is further provided in a second aspect of the present disclosure. The method includes: providing a substrate layer made of a III-V material; and forming a device structure and a waveguide structure on a surface of the substrate layer, wherein the device structure comprises a lower contact layer, a quantum well layer, and an upper contact layer; the lower contact layer, the quantum well layer, and the upper contact layer are sequentially stacked along a direction perpendicular to the substrate layer; the lower contact layer, the quantum well layer, and the upper contact later are made of the III-V material; and the waveguide structure comprises a waveguide layer made of the III-V material, the waveguide layer and the lower contact layer are disposed in one same layer.

### BRIEF DESCRIPTION OF THE DRAWINGS

FIG. 1A is a schematic top view of a homogeneous integrated infrared photonic chip according to one or more examples of the present disclosure;

FIG. 1B is a schematic top view of another homogeneous integrated infrared photonic chip according to one or more examples of the present disclosure;

FIG. 2 is a schematic sectional view along an X-axis direction of FIG. 1A;

FIG. 3 is a schematic sectional view along a Y-axis direction of FIG. 1A;

FIG. 4 is a schematic sectional view along a Y-axis direction of FIG. 1B;

FIG. 5 is a schematic flowchart of a method for manufacturing a homogeneous integrated infrared photonic chip according to one or more examples of the present disclosure; and

FIG. 6A is a schematic sectional view of processes in the manufacturing of the homogeneous integrated infrared photonic chip according to one or more examples of the present disclosure.

FIG. 6A is a schematic sectional view of processes in the manufacturing of the homogeneous integrated infrared photonic chip according to one or more examples of the present disclosure.

FIG. 6B is a schematic sectional view of processes in the manufacturing of the homogeneous integrated infrared photonic chip according to one or more examples of the present disclosure.

FIG. 6C is a schematic sectional view of processes in the manufacturing of the homogeneous integrated infrared photonic chip according to one or more examples of the present disclosure.

FIG. 6D is a schematic sectional view of processes in the manufacturing of the homogeneous integrated infrared photonic chip according to one or more examples of the present disclosure.

FIG. 6E is a schematic sectional view of processes in the manufacturing of the homogeneous integrated infrared photonic chip according to one or more examples of the present disclosure.

FIG. 6F is a schematic sectional view of processes in the manufacturing of the homogeneous integrated infrared photonic chip according to one or more examples of the present disclosure.

FIG. 6G is a schematic sectional view of processes in the manufacturing of the homogeneous integrated infrared photonic chip according to one or more examples of the present disclosure.

FIG. 6H is a schematic sectional view of processes in the manufacturing of the homogeneous integrated infrared photonic chip according to one or more examples of the present disclosure.

FIG. 6I is a schematic sectional view of processes in the manufacturing of the homogeneous integrated infrared photonic chip according to one or more examples of the present disclosure.

FIG. 6J is a schematic sectional view of processes in the manufacturing of the homogeneous integrated infrared photonic chip according to one or more examples of the present disclosure.

FIG. 6K is a schematic sectional view of processes in the manufacturing of the homogeneous integrated infrared photonic chip according to one or more examples of the present disclosure.

FIG. 6L is a schematic sectional view of processes in the manufacturing of the homogeneous integrated infrared photonic chip according to one or more examples of the present disclosure.

### DETAILED DESCRIPTION

A homogeneous integrated infrared photonic chip and a method for manufacturing the same according to the present disclosure are specifically described hereinafter in combination with the accompanying drawings.

Terms used in the present disclosure are merely for describing specific examples and are not intended to limit the present disclosure. The singular forms “one”, “the”, and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should be understood that although terms “first”, “second”, “third”, and the like are used in the present disclosure to describe various information, the information is not limited to the terms. These terms are merely used to differentiate information of a same type. For example, without departing from the scope of the present disclosure, first information is also referred to as second information, and similarly the second information is also referred to as the first information. Depending on the context, for example, the term “if” used herein may be explained as “when” or “while”, or “in response to . . . , it is determined that”.

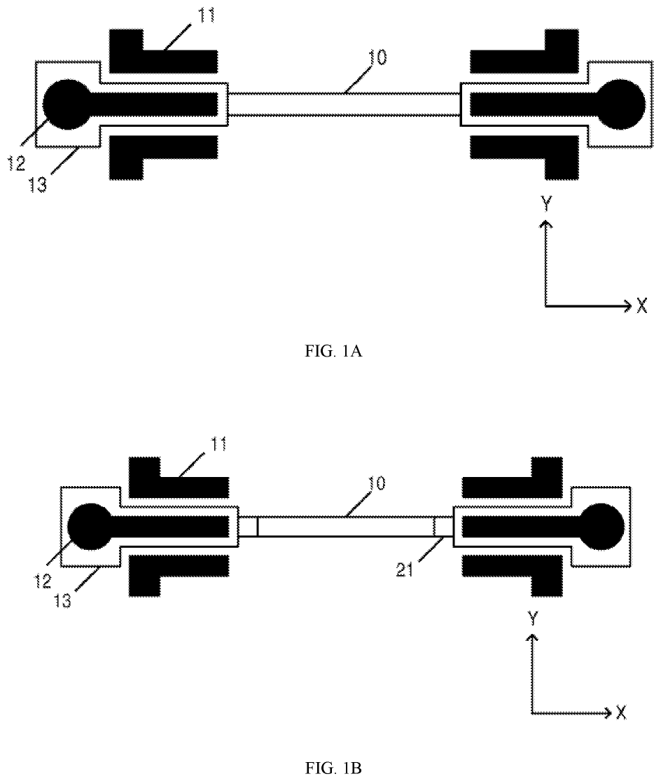

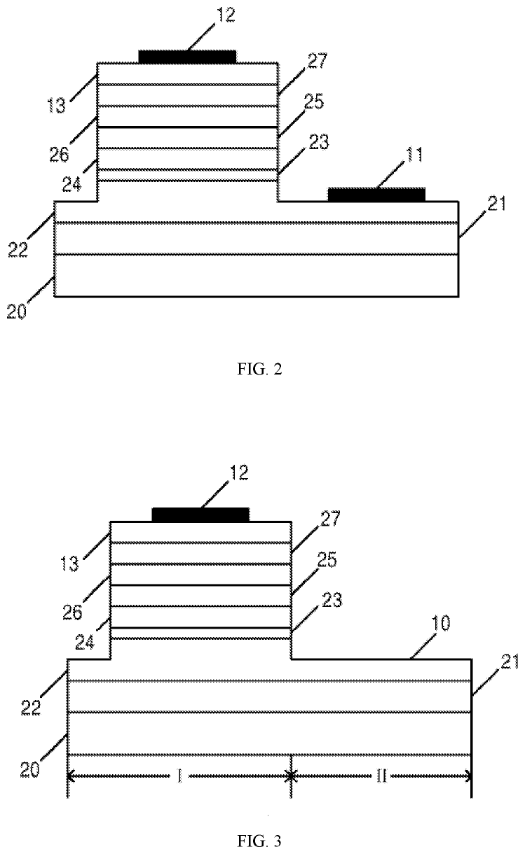

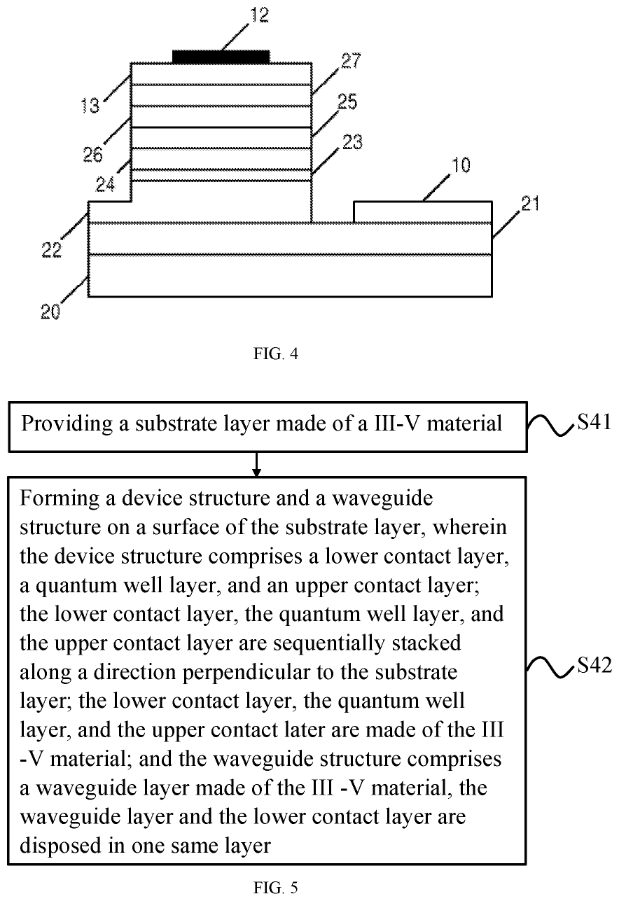

Examples of the present disclosure provide a homogeneous integrated infrared photonic chip. FIG. 1A is a schematic top view of a homogeneous integrated infrared photonic chip according to an example of the present disclosure. FIG. 1B is a schematic top view of another homogeneous integrated infrared photonic chip according to an example of the present disclosure. FIG. 2 is a schematic sectional view along an X-axis direction of FIG. 1A. FIG. 3 is a schematic sectional view along a Y-axis direction of FIG. 1A. FIG. 4 is a schematic sectional view along a Y-axis direction of FIG. 1B.

As illustrated in FIG. 1A and FIG. 1B, and FIG. 2 to FIG. 4, the specific examples provide a homogeneous integrated infrared photonic chip, including a substrate layer 20, and a device structure and a waveguide structure that are both positioned on a surface of the substrate layer 20.

The device structure includes a lower contact layer 22, a quantum well layer 23, and an upper contact layer 13 that are sequentially stacked along a direction perpendicular to the substrate layer 20. The substrate layer 20, the lower contact layer 22, the quantum well layer 23, and the upper contact layer 13 are made of a III-V material.

The waveguide structure includes a waveguide layer 10 made of the III-V material. The waveguide layer 10 and the lower contact layer 22 are arranged in the same layer.

The device structure and the waveguide structure are simultaneously integrated on the surface of the substrate layer 20 according to the specific examples. In the sectional view along the Y-axis direction in FIG. 1, the lower contact layer 22, the quantum well layer 23, and the upper contact layer 13 are sequentially stacked along the direction perpendicular to the substrate layer 20. In the sectional view along the X-axis direction in FIG. 1, the device structure and the waveguide layer 10 of the waveguide structure are arranged along a direction parallel to the substrate layer 20, and an infrared optical signal is transmitted between the device structure and the waveguide structure. In the specific examples, on-chip transmission of non-visible light of an infrared waveband is implemented, and the manufacturing difficulty and the manufacturing cost of an infrared communication device are reduced; in addition, a homogeneous integrated structure improves utilization efficiency of light sources of on-chip LED, and offers a new direction of developing photonic devices orientated to optical communication and optical sensing.

Alternatively or additionally, the homogeneous integrated infrared photonic chip further includes a buffer layer 21 positioned on the surface of the substrate layer 20 and made of the III-V material. The lower contact layer 22 and the waveguide layer 10 are both positioned on a surface of the buffer layer 21.

Specifically, an epitaxy of the buffer layer 21 is grown on the surface of the substrate layer 20, and a material of the buffer layer 21 and a material of the substrate layer 20 may be the same or different. The buffer layer 21 is configured to adjust stress between the substrate layer 20 and the device structure. The waveguide layer 10 and part of the buffer layer 21 positioned in a region under the waveguide layer 10 jointly form the waveguide structure.

Alternatively or additionally, the lower contact layer 22 is in a step-like shape. The step-like lower contact layer 22 includes a lower mesa and an upper mesa protrusively arranged on a surface of the lower mesa. The quantum well layer 23 and the upper contact layer 13 are sequentially stacked on the upper mesa. The waveguide layer 10 and the lower contact layer 22 are made of the same material.

Alternatively or additionally, the substrate layer 20 is an InP substrate layer, the lower contact layer 22 and the waveguide layer 10 are both an n-InP layer, and the upper contact layer 13 is a p-InGaAs layer.

The device structure includes the quantum well layer 23, a p-InP spacer layer 24, an etch barrier layer 25, a p-InP covering layer 26, a p-PQ gap buffer layer 27, and the p-InGaAs layer 28 that are sequentially stacked on a surface of the upper mesa along a direction of the substrate layer pointing to the device structure.

The PQ in the p-PQ gap buffer layer 27 represents a compound made of four elements of In, P, Ga, and As. In the homogeneous integrated infrared photonic chip manufactured by using a combination of various materials as described above, an optical wavelength generated by the device structure is 1550 nm, which pertains to non-visible light of an infrared waveband. Nevertheless, a person skilled in the art may further select other III-V materials to manufacture the device structure as needed, as long as the manufactured device structure is capable of generating an infrared optical signal.

Specifically, the buffer layer 21 may be an InP layer or a GaAs layer. The surface of the buffer layer 21 includes a device region having the device structure, and a waveguide region having the waveguide layer 10. The n-InP layer positioned in the device region forms the lower contact layer 22, and the lower contact layer 22 is in the step-like shape. The quantum well layer 23, the p-InP spacer layer 24, the etch barrier layer 25, the p-InP covering layer 26, the p-PQ gap buffer layer 27, and the p-InGaAs layer are sequentially stacked on the upper mesa along the direction perpendicular to the substrate layer 20. The n-InP layer positioned in the waveguide region forms the waveguide layer 10. For simplification of the manufacturing processes, the waveguide layer 10 and the lower mesa have an identical thickness.

In the specific examples, as illustrated in FIG. 1A and FIG. 3, an opening running through the n-InP layer along the direction perpendicular to the substrate layer 20 is arranged between the waveguide layer 10 and the lower contact layer 22.

In other specific examples, as illustrated in FIG. 1B and FIG. 4, the waveguide layer 10 is connected to the lower mesa of the lower contact layer 22, that is, the lower mesa of the lower contact layer 22 extends to the waveguide region, to form the waveguide layer 10.

A p-electrode 12 is positioned on a surface of the p-InGaAs layer, and an n-electrode 11 is positioned on a surface of the lower mesa of the lower contact layer 22. The p-electrode 12 and the n-electrode 11 may be made of titanium, platinum, or gold.

Alternatively or additionally, two device structures and a waveguide isolation slot positioned between the two device structures are arranged on the surface of the substrate layer 20. The waveguide structure is positioned at a bottom of the waveguide isolation slot, and configured to transmit an optical signal between the two device structures.

Specifically, the waveguide isolation slot is configured to electrically isolate the two device structures. The waveguide structure is positioned between two identical device structures. One of the device structures is used as a transmitter end of an optical signal, the other of the device structures is used as a receiver end of the optical signal, such that the infrared optical signal is transmitted between the transmitter end and the receiver end via the waveguide structure. The two device structures and the waveguide structure positioned between the two device structures form a pair of photonic communication devices. In the homogeneous integrated infrared photonic chip according to the specific examples, a pair of photonic communication devices, or multiple pairs of photonic communication devices may be included, and a person skilled in the art may make a selection as needed.

In the specific examples, no matter the lower contact layer 22 in the device structure is connected or not connected to the waveguide layer 10 in the waveguide structure, the two device structures may be electrically isolated by the waveguide isolation slot above the waveguide layer 10, thereby implementing homogeneous integration of an infrared photonic chip and on-chip transmission, and as well as simplifying the manufacturing processes of the homogeneous integrated infrared photonic chip. When the lower contact layer 22 is not connected to the waveguide layer 10, the two device structures may be better electrically isolated; and when the lower contact layer 22 is connected to the waveguide layer 10, the manufacturing processes may be greatly simplified.

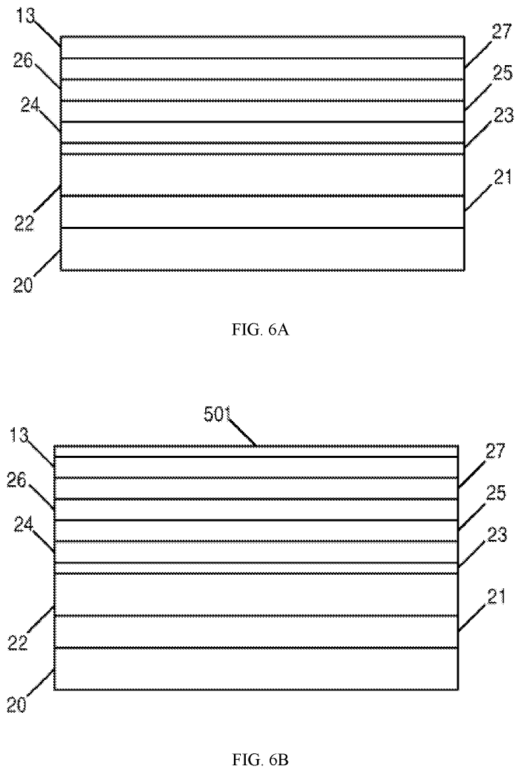

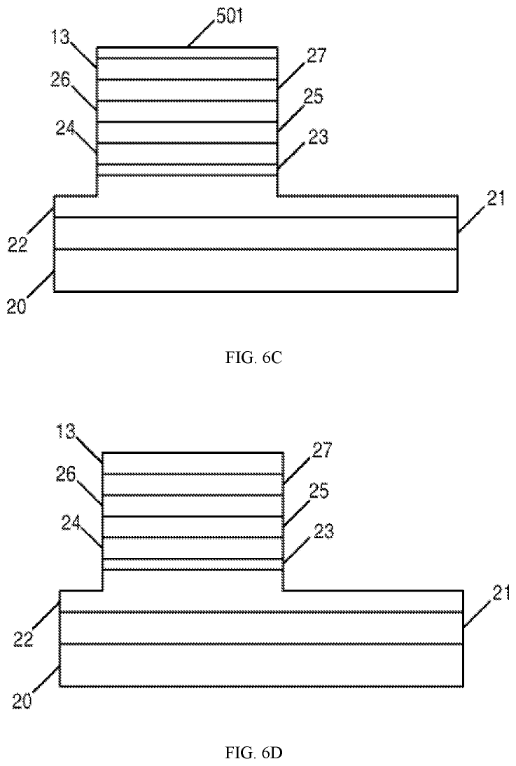

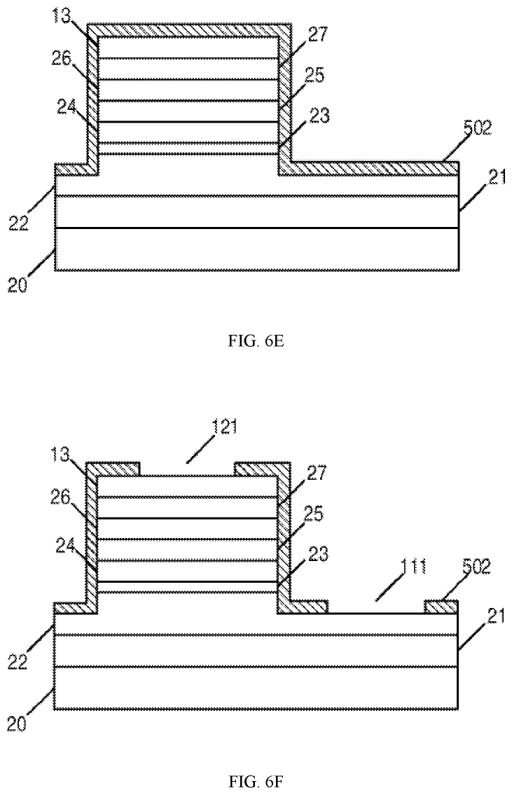

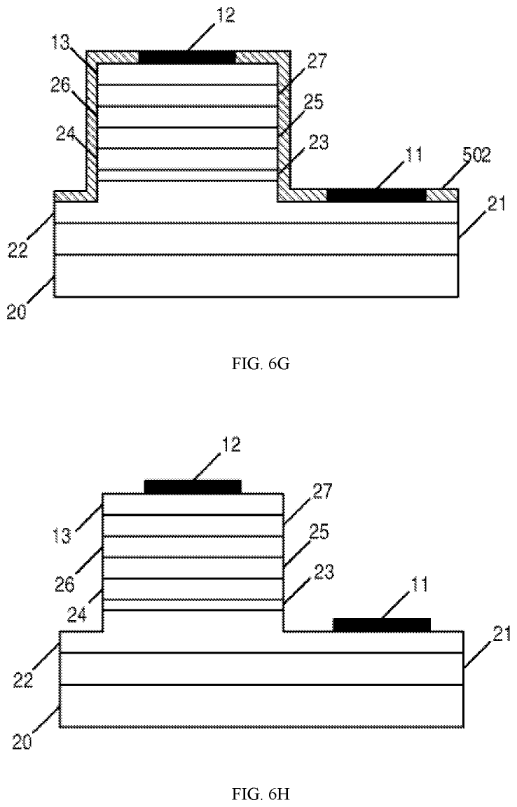

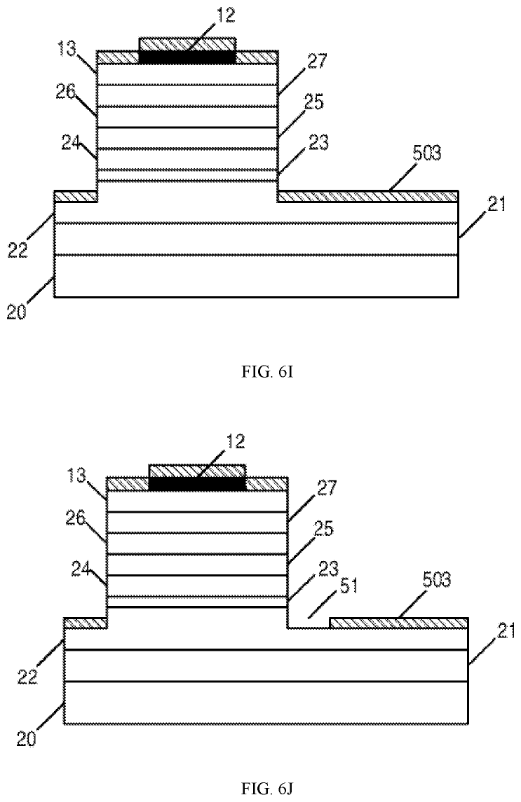

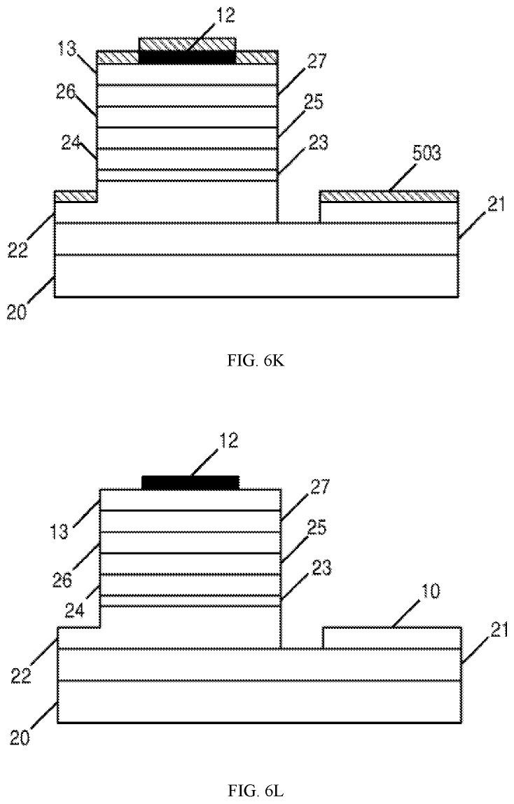

In addition, the specific examples further provide a method for manufacturing a homogeneous integrated infrared photonic chip. FIG. 5 is a schematic flowchart of a method for manufacturing a homogeneous integrated infrared photonic chip according to an example of the present disclosure. FIG. 6A to FIG. 6L are schematic sectional views of processes in the manufacturing of the homogeneous integrated infrared photonic chip according to an example of the present disclosure. For details about the structures of the homogeneous integrated infrared photonic chip manufactured according to the specific examples, reference may be made to FIG. 1A, FIG. 1B, and FIG. 2 to FIG. 4. As illustrated in FIG. 1A, FIG. 1B, FIG. 2 to FIG. 5, and FIG. 6A to FIG. 6L, the specific examples provide a method for manufacturing a homogeneous integrated infrared photonic chip. The method includes:

step S41: providing a substrate layer 20 made of a III-V material; and

step S42: forming a device structure and a waveguide structure on a surface of the substrate layer 20; wherein the device structure includes a lower contact layer 22, a quantum well layer 23, and an upper contact layer 13 that are sequentially stacked along a direction perpendicular to the substrate layer, the lower contact layer 22, the quantum well layer 23, and the upper contact layer 13 being made of the III-V material; and the waveguide structure includes a waveguide layer 10 made of the III-V material, the waveguide layer 10 and the lower contact layer 22 being arranged in the same layer.

Alternatively or additionally, prior to forming the device structure and the waveguide structure on the surface of the substrate layer 20, the method further includes:

forming a buffer layer 21 by depositing a first III-V material on the surface of the substrate layer 20.

Alternatively or additionally, forming the device structure and the waveguide structure on the surface of the substrate layer 20 may include:

forming a stack structure by sequentially depositing a second III-V material, a quantum well material, and a third III-V material on a surface of the buffer layer 21, as illustrated in FIG. 6A;

forming the device structure and the waveguide structure by etching the stack structure; wherein the device structure includes the lower contact layer 22 made of part of the second III-V material, the quantum well layer 23 made of the quantum well material, and the upper contact layer 13 made of the third III-V material; and the waveguide structure includes the waveguide layer 10 made of part of the second III-V material.

Alternatively or additionally, etching the stack structure may include:

defining a device region and a waveguide region in the stack structure; and

forming a step-like second III-V material layer by etching the stack structure, wherein the second III-V material layer includes a lower mesa and an upper mesa protrusively arranged on the lower mesa, wherein the quantum well layer 23 and the upper contact layer 13 are sequentially stacked on the upper mesa, the upper mesa and the lower mesa positioned in the device region form the lower contact layer 22, and the lower mesa forms the waveguide layer 10 by extending to the waveguide region.

The structure of the formed homogeneous integrated infrared photonic chip is as illustrated in FIG. 1A, FIG. 2, and FIG. 3. That is, the lower contact layer 22 is connected to the waveguide layer 10.

In other specific examples, for obtaining the structures as illustrated in FIG. 1B and FIG. 4, in response to etching the stack structure, the method further includes: forming an opening running through the buffer layer, and meanwhile forming the waveguide layer 10 formed of part of the lower mesa by etching the lower mesa between the waveguide region and the device region.

The first III-V material is an InP material, the second III-V material is an n-InP material, the third III-V material is a p-InGaAs, and the material of the substrate layer 20 is the InP material. Description is given hereinafter using forming the structure as illustrated in FIG. 1B and FIG. 4 as an example. Forming the device structure and the waveguide structure on the surface of the substrate layer 20 specifically includes:

(1) A stack structure is formed, as illustrated in FIG. 6A, by sequentially depositing an InP layer, an n-InP layer, a quantum well layer, a p-InP spacer layer, an etch barrier layer, a p-InP covering layer, a p-PQ gap buffer layer, and a p-InGaAs layer.

(2) A layer of a first photoresist layer 501 is uniformly coated on a surface of the stack structure as illustrated in FIG. 6B, and the device region and waveguide region are defined in the first photoresist layer 501.

(3) A step-like structure as illustrated in FIG. 6C is formed by etching the stack structure using a reactive ion beam, and the structure as illustrated in FIG. 6D is finally obtained after a residual first photoresist layer 501 is removed. Specifically, a step-like n-InP layer is formed by etching the stack structure. The n-InP layer positioned in the device region includes the lower mesa and the upper mesa protrusively arranged on a surface of the lower mesa, and the lower mesa of the n-InP layer extends to the waveguide region. Meanwhile, the quantum well layer, the p-InP spacer layer, the etch barrier layer, the p-InP covering layer, the p-PQ gap buffer layer, and the p-InGaAs layer that are positioned on the upper mesa are only reserved; and the quantum well layer, the p-InP spacer layer, the etch barrier layer, the p-InP covering layer, the p-PQ gap buffer layer, and the p-InGaAs layer that are positioned on the lower mesa are all removed. The quantum well layer 23, the p-InP spacer layer 24, the etch barrier layer 25, the p-InP covering layer 26, the p-PQ gap buffer layer 27, and the upper contact layer 13 that are positioned on the upper mesa are formed while a waveguide isolation slot is formed; and a step-like n-InP material layer positioned in the device region forms the lower contact layer 22.

(4) A layer of a second photoresist layer 502 is uniformly coated on the surface of the structure in FIG. 6D, as illustrated in FIG. 6E. A p-electrode window region 121 and an n-electrode window region 111 are defined in the second photoresist layer 502 as illustrated in FIG. 6F. An ohmic contact is formed by vapor deposition of titanium, platinum, or gold in the p-electrode window region 121 and the n-electrode window region 111, such that the p-electrode 12 and the n-electrode 11 are obtained as illustrated in FIG. 6G. An LED structure as illustrated in FIG. 6H is finally obtained after a residual second photoresist layer 502 is removed.

(5) A layer of a third photoresist layer 503 is uniformly coated on the surface of the substrate layer 20 of the LED structure in FIG. 6H, as illustrated in FIG. 6I. The waveguide region, the device region, and a spacer region 51 between the waveguide region and the device region are further defined in the third photoresist layer as illustrated in 6J. Subsequently, an opening running through the lower mesa is formed by etching, using a reactive ion beam, the lower mesa of the n-InP material layer positioned in the spacer region 51 to the buffer 21 as illustrated in FIG. 6K. The structure as illustrated in FIG. 6L is finally obtained after a residual third photoresist layer 503 is removed.

Alternatively or additionally, two device structures and a waveguide isolation slot positioned between the two device structures are arranged on the surface of the substrate layer 20. The waveguide structure is positioned at a bottom of the waveguide isolation slot, and configured to transmit an optical signal between the two device structures.

Specifically, since the two device structures are totally identical, the two device structures and the waveguide structure may be synchronously manufactured, such that the manufacturing processes of the homogeneous integrated infrared photonic chip are further simplified, and the manufacturing cost is reduced.

In the homogeneous integrated infrared photonic chip and the method for manufacturing the same according to the specific examples, the waveguide structure and the device structure are integrated into the substrate made of the III-V material and are made of the III-V material, and a gap is defined between the waveguide structure and the device structure, such that homogeneous integration of the waveguide structure and the device structure is achieved, on-chip transmission of non-visible light of an infrared waveband is further implemented, and the manufacturing difficulty and the manufacturing cost of an infrared light communication device are reduced.

Alternatively or additionally, the homogeneous integrated infrared photonic chip further includes a buffer layer positioned on the surface of the substrate layer and made of the III-V material, wherein the lower contact layer and the waveguide layer are both positioned on a surface of the buffer layer.

Alternatively or additionally, the lower contact layer is in a step-like shape; wherein the step-like lower contact layer includes a lower mesa and an upper mesa protrusively arranged on a surface of the lower mesa, the quantum well layer and the upper contact layer are sequentially stacked on the upper mesa, and the waveguide layer and the lower contact layer are made of the same material.

Alternatively or additionally, the substrate layer is an InP substrate layer, the lower contact layer and the waveguide layer are both an n-InP layer, and the upper contact layer is a p-InGaAs layer;

wherein the device structure includes the quantum well layer, a p-InP spacer layer, an etch barrier layer, a p-InP covering layer, a p-PQ gap buffer layer, and the p-InGaAs layer that are sequentially stacked on a surface of the upper mesa along a direction of the substrate layer pointing to the device structure.

Alternatively or additionally, two device structures and a waveguide isolation slot positioned between the two device structures are arranged on the surface of the substrate layer; and the waveguide structure is positioned at a bottom of the waveguide isolation slot, and configured to transmit an optical signal between the two device structures.

Alternatively or additionally, prior to forming the device structure and the waveguide structure on the surface of the substrate layer, the method further includes:

forming a buffer layer by depositing a first III-V material on the surface of the substrate layer.

Alternatively or additionally, forming the device structure and the waveguide structure on the surface of the substrate layer may include:

forming a stack structure by sequentially depositing a second III-V material, a quantum well material, and a third III-V material on a surface of the buffer layer; and

forming the device structure and the waveguide structure by etching the stack structure; wherein the device structure includes the lower contact layer made of part of the second III-V material, the quantum well layer made of the quantum well material, and the upper contact layer made of the third III-V material; and the waveguide structure includes the waveguide layer made of part of the second III-V material.

Alternatively or additionally, etching the stack structure may include:

defining a device region and a waveguide region in the stack structure; and

forming a step-like second III-V material layer by etching the stack structure, wherein the second III-V material layer includes a lower mesa and an upper mesa protrusively arranged on the lower mesa, wherein the quantum well layer and the upper contact layer are sequentially stacked on the upper mesa, the upper mesa and the lower mesa positioned in the device region form the lower contact layer, and the lower mesa forms the waveguide layer by extending to the waveguide region.

Alternatively or additionally, two device structures and a waveguide isolation slot positioned between the two device structures are arranged on the surface of the substrate layer; and the waveguide structure is positioned at a bottom of the waveguide isolation slot, and configured to transmit an optical signal between the two device structures.

In the homogeneous integrated infrared photonic chip and the method for manufacturing the same according to the present disclosure, the waveguide structure and the device structure are integrated into the substrate made of the III-V material and are made of the III-V material, and the lower contact layer in the device structure and the waveguide layer in the waveguide structure are arranged in the same layer, such that homogeneous integration of the waveguide structure and the device structure is achieved, on-chip transmission of non-visible light of an infrared waveband is further implemented, and the manufacturing difficulty and the manufacturing cost of an infrared light communication device are reduced.

Described above are examples of the present disclosure. It should be noted that persons of ordinary skill in the art may derive other improvements without departing from the principles of the present disclosure. Such improvements shall be deemed as falling within the protection scope of the present disclosure.

What is claimed is:

1. A homogeneous integrated infrared photonic chip, comprising:
a substrate layer, a device structure, and a waveguide structure, wherein the device structure and the waveguide structure are both disposed on a surface of the substrate layer;
wherein the device structure comprises a lower contact layer, a quantum well layer, and an upper contact layer; the lower contact layer, the quantum well layer, and the upper contact layer are sequentially stacked along a direction perpendicular to the substrate layer; and the substrate layer, the lower contact layer, the quantum well layer, and the upper contact layer are made of a III-V material; and
wherein the waveguide structure comprises a waveguide layer made of the III-V material, and the waveguide layer and the lower contact layer are disposed in one same layer.

2. The homogeneous integrated infrared photonic chip according to claim 1, further comprising: a buffer layer, disposed on the surface of the substrate layer and made of the III-V material, wherein the lower contact layer and the waveguide layer are both disposed on a surface of the buffer layer.

3. The homogeneous integrated infrared photonic chip according to claim 1, wherein the lower contact layer is in a step-like shape, wherein the step-like lower contact layer comprises a lower mesa, and an upper mesa protrusively arranged on a surface of the lower mesa, the quantum well layer and the upper contact layer are sequentially stacked on the upper mesa, and the waveguide layer and the lower contact layer are made of a same material.

4. The homogeneous integrated infrared photonic chip according to claim 3, wherein the substrate layer is an InP substrate layer, the lower contact layer and the waveguide layer are both an n-InP layer, and the upper contact layer is a p-InGaAs layer; and
wherein the device structure comprises the quantum well layer, a p-InP spacer layer, an etch barrier layer, a p-InP covering layer, a p-PQ gap buffer layer, and the p-InGaAs layer that are sequentially stacked on a surface of the upper mesa along a direction of the substrate layer pointing to the device structure.

5. The homogeneous integrated infrared photonic chip according to claim 1, wherein two device structures and a waveguide isolation slot positioned between the two device structures are disposed on the surface of the substrate layer, and the waveguide structure is disposed at a bottom of the waveguide isolation slot, and configured to transmit an optical signal between the two device structures.

6. A method for manufacturing a homogeneous integrated infrared photonic chip, comprising:
providing a substrate layer made of a III-V material; and
forming a device structure and a waveguide structure on a surface of the substrate layer, wherein the device structure comprises a lower contact layer, a quantum well layer, and an upper contact layer; the lower contact layer, the quantum well layer, and the upper contact layer are sequentially stacked along a direction perpendicular to the substrate layer; the lower contact layer, the quantum well layer, and the upper contact later are made of the III-V material; and the waveguide structure comprises a waveguide layer made of the III-V material, the waveguide layer and the lower contact layer are disposed in one same layer.

7. The method according to claim 6, wherein prior to forming the device structure and the waveguide structure on the surface of the substrate layer, the method further comprises:
forming a buffer layer by depositing a first III-V material on the surface of the substrate layer.

8. The method according to claim 7, wherein forming the device structure and the waveguide structure on the surface of the substrate layer comprises:
forming a stack structure by sequentially depositing a second III-V material, a quantum well material, and a third III-V material on a surface of the buffer layer; and
forming the device structure and the waveguide structure by etching the stack structure; wherein the device structure comprises the lower contact layer made of part of the second III-V material, the quantum well layer made of the quantum well material, and the upper contact layer made of the third III-V material; and the waveguide structure comprises the waveguide layer made of part of the second III-V material.

9. The method according to claim 8, wherein etching the stack structure comprises:
defining a device region and a waveguide region in the stack structure; and
forming a step-like second III-V material layer by etching the stack structure, wherein the second III-V material layer comprises a lower mesa, and an upper mesa protrusively arranged on the lower mesa, wherein the quantum well layer and the upper contact layer are sequentially stacked on the upper mesa, the upper mesa and the lower mesa positioned in the device region form the lower contact layer, and the lower mesa forms the waveguide layer by extending to the waveguide region.

10. The method according to claim 6, wherein two device structures and a waveguide isolation slot positioned between the two device structures are disposed on the surface of the substrate layer, wherein the waveguide structure is disposed at a bottom of the waveguide isolation slot, and configured to transmit an optical signal between the two device structures.
